(19) United States
(12) Patent Application Publication
(10) Pub. No.: US 2026/0082919 A1
(43) Pub. Date: Mar. 19, 2026

(54) MODIFIED DICING STREET FOR HYBRID BONDING

(71) Applicant: International Business Machines Corporation, Armonk, NY (US)

(72) Inventors: Aakrati Jain, Albany, NY (US); Michael Rizzolo, Delmar, NY (US); Sagarika Mukesh, ALBANY, NY (US); Hosadurga Shobha, Niskayuna, NY (US); Christopher J. Waskiewicz, Rexford, NY (US)

(21) Appl. No.: 18/888,121

(22) Filed: Sep. 17, 2024

(51) Int. Cl. H01L 23/00; H01L 21/683; H01L 21/762

(52) U.S. Cl. CPC H10W 42/121; H10P 72/7402; H10P 90/1916; H10W 10/181

(57) ABSTRACT

Semiconductor devices having a modified dicing street for hybrid bonding are provided. In one aspect, a semiconductor device includes: at least one die having a metal disposed on a semiconductor wafer, where a portion of the metal present along at least one edge of the at least one die includes an implant selected from: bismuth, hydrogen, and combinations thereof. The at least one die may be used for hybrid bonding via a combination of metal and dielectric bonds. A method of fabricating the present semiconductor devices is also provided.

### BACKGROUND

The present invention relates generally to the electrical, electronic and computer arts and, more particularly, to semiconductor devices having a modified dicing street for hybrid bonding, and wafer dicing techniques for fabrication thereof.

Integrated circuit manufacturing typically involves fabricating a multitude of semiconductor devices on a common semiconductor wafer, and then using a process known as ‘die singulation’ to physically cut-up or dice the semiconductor wafer into the separate individual dies. Bonding techniques such as hybrid bonding can be employed for packaging the dies. Unlike traditional approaches such as flip chip, hybrid bonding employs copper-to-copper connections to connect dies in packages and is more highly scalable.

Commonly employed techniques for die singulation can, however, present some notable challenges for advanced packaging techniques like hybrid bonding. For instance, saw dicing employs a mechanical blade to cause separation which can generate debris at the dicing edge that is unsuitable for hybrid bonding. Laser dicing, on the other hand, uses an ultraviolet (UV) laser from the topside of the semiconductor wafer to ablate material. However, with metal components, ablating causes remelt to form at the dicing edge making it uneven and thus also unsuitable for hybrid bonding.

### BRIEF SUMMARY

Principles of the invention provide semiconductor devices having a modified dicing street for hybrid bonding, and wafer dicing techniques for fabrication thereof.

In one aspect, a semiconductor device includes: at least one die having a metal disposed on a semiconductor wafer, where a portion of the metal present along at least one edge of the at least one die includes an implant selected from: bismuth, hydrogen, and combinations thereof.

In another aspect, another exemplary semiconductor device includes: a first component bonded to a second component via a combination of metal and dielectric bonds, where the first component, the second component or both the first component and the second component includes a die having a metal disposed on a semiconductor wafer, and where a portion of the metal present along at least one edge of the die includes an implant selected from: bismuth, hydrogen, and combinations thereof.

In yet another aspect, an exemplary method includes: embrittling a metal disposed on a front side of a semiconductor wafer that is mounted on a dicing tape to form a brittle metal in a dicing street of the semiconductor wafer; using a laser from a back side of the semiconductor wafer to melt the semiconductor wafer along the dicing street of the semiconductor wafer; and expanding the dicing tape to separate the semiconductor wafer into individual dies, where the brittle metal in the dicing street of the semiconductor wafer acts as a site for crack initiation and propagation during the expanding of the dicing tape.

As used herein, “facilitating” an action includes performing the action, making the action easier, helping to carry the action out, or causing the action to be performed. Thus, by way of example and not limitation, instructions executing on one processor might facilitate an action carried out by semiconductor processing equipment, by sending appropriate data or commands to cause or aid the action to be performed. Where an actor facilitates an action by other than performing the action, the action is nevertheless performed by some entity or combination of entities.

Techniques as disclosed herein can provide substantial beneficial technical effects. Some embodiments may not have these potential advantages and these potential advantages are not necessarily required of all embodiments. By way of example only and without limitation, one or more embodiments may provide one or more of:
Easy and effective die singulation techniques which result in minimal surface defects around die edges, even when metal (e.g., metal fill, test structures, etc.) is present in dicing lanes;
With minimal surface defects, the present techniques can be implemented in conjunction with advanced packaging techniques such as hybrid bonding, thus enhancing scaling capabilities;
The present techniques can be integrated into a stealth dicing routine, thereby avoiding the debris and remelt at the dicing edge often caused by saw dicing and laser dicing from the topside of the semiconductor wafer.

These and other features and advantages will become apparent from the following detailed description of illustrative embodiments thereof, which is to be read in connection with the accompanying drawings.

### BRIEF DESCRIPTION OF THE DRAWINGS

The following drawings are presented by way of example only and without limitation, wherein like reference numerals (when used) indicate corresponding elements throughout the several views, and wherein:

FIG. 1 is a diagram illustrating an exemplary process for determining when to employ the present Embrittlement Enhanced Stealth Dicing (EESD) techniques according to one or more embodiments of the present invention;

FIG. 2 is a diagram providing an overview of the present process for embrittlement of metal in the dicing street for crack initiation and propagation during die singulation according to one or more embodiments of the present invention;

FIGS. 3-6 are cross-sectional diagrams illustrating masking used for the present EESD techniques according to one or more embodiments of the present invention;

FIGS. 7-10 are cross-sectional diagrams illustrating an alternative mask-less EESD process according to one or more embodiments of the present invention;

FIG. 11 is a cross-sectional diagram illustrating an example of face-to-face hybrid bonding of two of the present EESD-produced dies according to one or more embodiments of the present invention; and

FIGS. 12-17 are cross-sectional diagrams illustrating an exemplary implementation of the present EESD process where ion implantation for embrittlement of metal in the dicing street is carried out as each one of multiple metal levels is formed on a semiconductor wafer according to one or more embodiments of the present invention.

It is to be appreciated that elements in the figures are illustrated for simplicity and clarity. Common but well-understood elements that may be useful or necessary in a commercially feasible embodiment may not be shown in order to facilitate a less hindered view of the illustrated embodiments.

### DETAILED DESCRIPTION

Principles of inventions described herein will be in the context of illustrative embodiments. Moreover, it will become apparent to those skilled in the art given the teachings herein that numerous modifications can be made to the embodiments shown that are within the scope of the claims. That is, no limitations with respect to the embodiments shown and described herein are intended or should be inferred.

As highlighted above, some traditional die singulation methods such as saw dicing and laser dicing have features that are incompatible with advanced packing techniques like hybrid bonding. For instance, saw dicing generates debris, while laser dicing causes metal remelt to form at the dicing edges (i.e., at the edges of the die).

Alternative methods such as stealth dicing can be employed to avoid debris and remelt during die singulation. With stealth dicing, an ultraviolet (UV) laser is used from the back side to melt silicon in the center of the semiconductor wafer. A crack or fracture is then propagated by expanding the carrier material (e.g., dicing tape on which the dies are formed). However, stealth dicing is unable to cut through metal. As a result, any metal in the dicing street prevents separation during expansion of the carrier material (e.g., dicing tape).

Advantageously, provided herein are improved dicing techniques which employ ion implantation along the dicing street to cause embrittlement of the metal specifically along the dicing edges where die separation is desired. Afterwards, a process such as stealth dicing can then be employed to complete die singulation. During the stealth dicing, when the dicing tape is expanded, the embrittled metal will advantageously enable easy and effective fracture propagation along the dicing street. This process combining embrittlement and stealth dicing is also referred to herein as Embrittlement Enhanced Stealth Dicing (EESD).

The terms ‘dicing street’ or ‘dicing lane’ which are used interchangeably herein refer to the intended cutting lines, that run parallel to the surface of a semiconductor wafer, along which the semiconductor wafer is cut into the separate individual dies. Hence, the edges of the dies resulting from singulation are referred to herein as “dicing edges.” As will be described in detail below, these dicing edges will contain metal that has been embrittled as a result of the present process. More specifically, the dicing edges will contain an implant (see below) that is used to create the embrittlement specifically along the dicing street. For instance, one type of implant considered herein is a metallic element such as bismuth. As known by those having ordinary skill in the art, a metallic alloy consists of a metal in combination with another metal or non-metal element. An intermetallic compound is a type of metallic alloy that forms an ordered solid-state compound between two or more metallic elements. Thus, when an implant such as bismuth (a metallic element) is introduced into the metal in the dicing street, the implant will segregate to grain boundaries in the metal, i.e., interfaces between grains in the microstructure of the metal. This segregation promotes the preferential formation of an intermetallic compound such as Cu₃Bi and/or Cu₅Bi₈ at the grain boundaries, which act as sites for crack initiation and propagation during dicing tape expanding/stretching.

Another type of implant considered herein is a nonmetallic element such as hydrogen. Several different mechanisms for hydrogen embrittlement have been proposed, including hydrogen-enhanced decohesion, hydrogen-enhanced local plasticity, and hydride formation and cleavage. With hydride formation and cleavage, the combination of active species such as hydrogen and oxygen (i.e., a hydride of oxygen) create a brittle oxide.

In general, hybrid bonding is a thermo-compressive bonding process that combines both dielectric and metal bonding to form interconnections. In hybrid bonding, a permanent bond combines a dielectric bond (e.g., SiOx) with embedded metal (e.g., Cu) to form interconnections. Two interconnect structures or semiconductor builds are joined together (e.g., two individual wafers that are built separately). They typically require a “pristine” surface (smooth and flat, possibly with some recesses), more so than traditional chemical-mechanical planarization (CMP). The two semiconductor builds are purposely designed to align. The term “hybrid” refers to the presence of both copper and dielectric. A bond that uses dielectric alone is referred to as fusion bonding (oxide to oxide). Hybrid bonding uses metal to metal connections for the copper. Two semiconductor builds are brought together and a small heat treatment/annealing process is carried out. The oxides bond together and the metals “anneal,” or almost melt, together, thus fusing the interface into a single bonded part (in some instances, seamlessly; i.e., the interface line disappears).

Semiconductor device manufacturing often includes the implementation of standard metallization processes for the formation of elements such as interconnects, test structures, etc. During these metallization processes, metal can be deposited into the dicing street between adjacent dies. For die singulation, this metal between dies must be cleanly divided to effectively separate the individual dies. While processes such as saw dicing or laser dicing can cut through metal in the dicing street, they generate byproducts that are incompatible with hybrid bonding, such as debris and remelt.

Thus, as highlighted above, the present Embrittlement Enhanced Stealth Dicing (EESD) techniques are particularly useful in die singulation processes where there is metal present in the dicing street and where an advanced bonding technique such as hybrid bonding (which requires well matched bonding surfaces free of debris or remelt) will be employed. As described in detail above, metal in the dicing street presents a notable challenge for stealth dicing as the metal cannot be cut and prevents separation during expansion of the dicing tape. While alternate methods such as saw dicing or laser dicing can cut metal in the dicing street, they are not compatible with hybrid bonding scenarios since they result in the formation of debris or remelt, as the case may be, at the dicing edges.

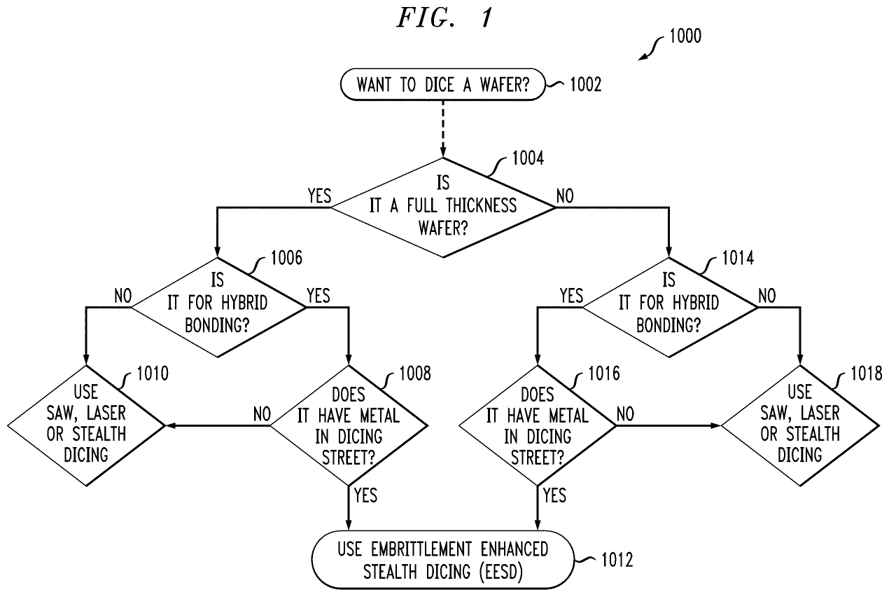

For instance, FIG. 1 is a diagram illustrating an exemplary process 1000 for determining when to employ the present EESD techniques. Notably, as highlighted above, the decision will be largely based on whether the dies will be used for hybrid bonding and, if so, whether metal is present in the dicing street.

More specifically, if the task at hand involves wafer dicing (step 1002), then in step 1004 a determination is made as to whether that wafer dicing will be performed on a full thickness wafer. The term ‘full thickness wafer’ simply refers to a semiconductor (e.g., silicon (Si), germanium (Ge), silicon germanium (SiGe), III-V, etc.) wafer that is at its standard production thickness, i.e., it has not been thinned. By way of example only, commercially available Si wafers typically have a thickness of from about 175 micrometers (μm) to about 180 μm. If it is determined in step 1004 that (Yes) wafer dicing will be performed on a full thickness wafer then, in step 1006, a determination is made as to whether the singulated dies will be used for hybrid bonding. As described in detail above, hybrid bonding is a thermo-compressive bonding process that combines both dielectric and metal bonding to form interconnections, a process which requires remelt-free and debris-free bonding surfaces.

As highlighted above, the next important determination is whether the semiconductor wafer for dicing has metal in the dicing street. Namely, as described in detail above, metallization is often a common part of the semiconductor device fabrication process. Metallization can, however, result in metal being deposited on the semiconductor wafer in the dicing street between adjacent dies. Thus, in step 1008, a determination is made as to whether there is metal present in the dicing street.

If it is determined in step 1006 that (No) the singulated dies will not be used for hybrid bonding, then a conventional die singulation process such as saw dicing, laser dicing, or stealth dicing can be employed. See step 1010. Even if it determined in step 1006 that (Yes) the singulated dies will be used for hybrid bonding, but it is determined in step 1008 that (No) there is no metal present in the dicing street, then saw dicing, laser dicing, or stealth dicing can similarly be employed. See step 1010.

On the other hand, the use of hybrid bonding (step 1006) AND the presence of metal in the dicing street (step 1008) requires that the present Embrittlement Enhanced Stealth Dicing (EESD) be employed in order to ensure remelt-free and debris-free bonding surfaces for hybrid bonding (which cannot be achieved by the conventional die singulation processes). See step 1012. Namely, as highlighted above, saw dicing and laser dicing result in debris and remelt, as the case may be, which is unsuitable for hybrid bonding, and stealth dicing alone cannot cut metal in the dicing street. Advantageously, the present EESD process will cause embrittlement of the metal specifically along the dicing edge. Thus, when the dicing tape is expanded, the embrittled metal will enable fracture propagation along the dicing lanes.

Referring back to step 1004, if it is determined that (No) it is not a full thickness wafer (e.g., the wafer has been thinned) then, in step 1014, a determination is also made as to whether the singulated dies will be used for hybrid bonding. A similar decision process to above is then followed if it is determined that hybrid bonding will not be used (step 1014) and/or if it is determined that there is no metal in the dicing street (step 1016). Namely, if it is determined in step 1014 that (No) the singulated dies will not be used for hybrid bonding, then a conventional die singulation process such as saw dicing, laser dicing, or stealth dicing can be employed. See step 1018. Even if it is determined in step 1014 that (Yes) the singulated dies will be used for hybrid bonding, but it is determined in step 1016 that (No) there is no metal present in the dicing street, then saw dicing, laser dicing, or stealth dicing can similarly be employed. See step 1018.

On the other hand, the use of hybrid bonding (step 1014) AND the presence of metal in the dicing street (step 1016) requires that the present Embrittlement Enhanced Stealth Dicing (EESD) be employed in order to ensure remelt-free and debris-free bonding surfaces for hybrid bonding (which cannot be achieved by the conventional die singulation processes). See step 1012. Namely, as highlighted above, the present EESD process will cause embrittlement of the metal specifically along the dicing edge. Thus, when the dicing tape is expanded, the embrittled metal will enable fracture propagation along the dicing lanes.

As highlighted above, the present techniques employ embrittlement of metal such as copper through the implantation of metallic and/or nonmetallic elements such as bismuth and/or hydrogen into the semiconductor wafer along the dicing street, i.e., along the dicing edges of the dies. These implants will embrittle the metal along the dicing street, and act as sites for crack initiation and propagation during dicing tape stretching.

As highlighted above, a metallic alloy consists of a metal in combination with another (metallic or nonmetallic) element. By way of example only, when copper is the metal present in the dicing street, implantation of bismuth can result in the formation of an intermetallic compound containing copper and bismuth such as Cu₃Bi and/or Cu₅Bi₈. These intermetallic compounds have different crystal structures and mechanical properties (most notably a reduced fracture resistance) as compared to pure copper. Similarly, implantation of hydrogen into copper can result in the formation of a hydride such as a brittle hydride of oxygen that has a reduced fracture resistance as compared to pure copper.

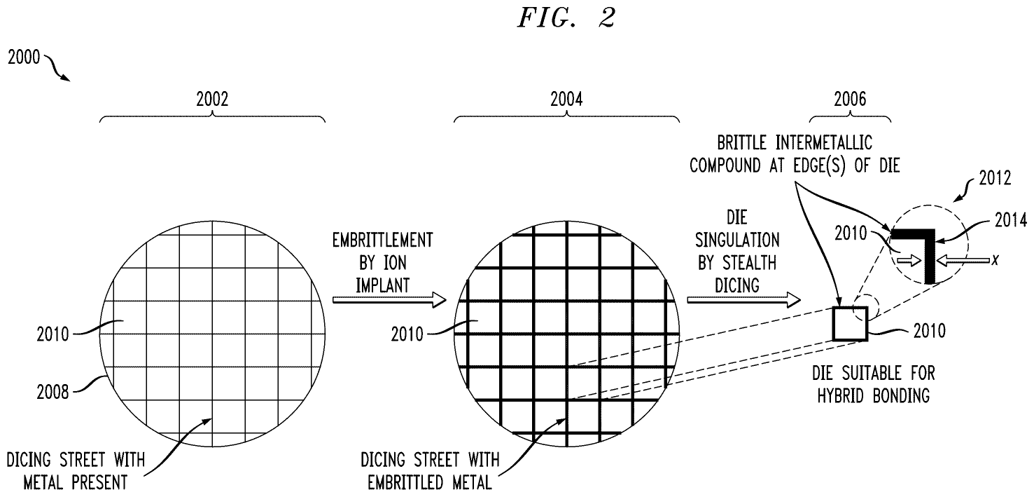

For instance, referring to an overview of the present Embrittlement Enhanced Stealth Dicing (EESD) process 2000 shown in FIG. 2 it can be seen in step 2002 that a plurality of dies 2010 have been formed on a common semiconductor wafer 2008. Further, in this example, there is metal such as copper present in the dicing street. As described above, having metal present in the dicing street is one of the important considerations in choosing to implement the present EESD process. The other is whether the dies will be used for hybrid bonding. For this example, it is assumed that, the dies resulting from this EESD process 2000 will be used for hybrid bonding.

In step 2004, an ion implant is performed to embrittle the metal in the dicing street. Preferably, this embrittlement process is limited to the metal in the dicing street (i.e., the embrittled metal is present only in the dicing street). According to an exemplary embodiment, bismuth and/or hydrogen ions are implanted in the dicing street in step 2004. As highlighted above, this process will embrittle the metal in the dicing street which then acts as a site for crack initiation and propagation during dicing tape stretching.

Namely, in step 2006 stealth dicing is then employed to singulate the wafer into individual ones of the dies 2010. For illustrated purposes only, one of these dies 2010 is shown in FIG. 2. As provided above, stealth dicing employs a UV laser from the back side of the semiconductor wafer 2008. A crack or fracture is then propagated by expanding the dicing tape (not shown) on which the dies are formed. Advantageously, while stealth dicing is unable to cut metal, what metal that is present in the dicing street has been embrittled by the ion implant in step 2004. Thus, when the dicing tape is expanded, the embrittled metal will act as sites for crack initiation and propagation. Hence, the stealth dicing process is enhanced by the embrittlement process.

As shown in step 2006, the embrittled metal in the dicing street containing the implant will remain present along at least one edge of each of the (singulated) dies 2010, thus indicating that the present EESD process 2000 has been employed. Notably, stealth dicing without the present embrittlement enhancement could not be used since, as highlighted above, metal such as pure copper present in the dicing lanes would prevent clean separation of the dies 2010.

By way of example only, the term ‘edge’ refers to a region x along a perimeter of each of the dies that is from about 300 nanometers (nm) to about 500 nm in from an outermost side 2014 of each of the dies. See, for example, magnified view 2012. According to an exemplary embodiment, the embrittled metal containing the implant is present only at the edge(s) of each of the dies 2010.

In one exemplary embodiment, the embrittlement process is limited to the edge of the dies 2010 using a masking process to limit the ion implantation process to the dicing street. See, for example, FIGS. 3-6. For example, referring to FIG. 3, the process begins with a structure 3000 that includes a semiconductor wafer 3002 mounted on a dicing tape 3004. According to an exemplary embodiment, semiconductor wafer 3002 is a bulk silicon (Si), bulk germanium (Ge), bulk silicon germanium (SiGe) and/or bulk III-V semiconductor wafer. Semiconductor wafer 3002 may have pre-built structures (not shown) such as transistors, diodes, capacitors, resistors, interconnects, wiring, etc.

Dicing tape 3004 may be any commercially-available dicing tape which includes a backing material such as polyvinyl chloride (PVC), polyolefin and/or polyethene, and an adhesive for attaching the dicing tape to a back side of the semiconductor wafer 3002. As highlighted above, the dicing tape 3004 will be employed later on in the process during die singulation when it is expanded to propagate fractures along the dicing street.

In this particular example, metal 3006 embedded in a dielectric 3008 is disposed on a front side of the semiconductor wafer 3002, including within a dicing street 3010. According to an exemplary embodiment, metal 3006 is copper. Further, while not explicitly shown, metal 3006 may be composed of multiple metal levels built one on top of another. Suitable dielectric 3008 materials include, but are not limited to, oxide low-κ materials such as silicon oxide (SiOx) and/or oxide ultralow-κ interlayer dielectric (ULK-ILD) materials, e.g., having a dielectric constant κ of less than 2.7. Suitable ultralow-κ dielectric materials include, but are not limited to, porous organosilicate glass (pSiCOH).

As shown in FIG. 3, crackstop structures 3012 are present on opposite sides of the dicing street 3010. As known by those having ordinary skill in the art, crackstop structures (or simply ‘crackstops’) are typically employed to prevent die edge cracks from propagating to the active area of a die due, for example, to thermal cycling of the die during use. By way of example only, crackstop structures 3012 can be formed from a metal(s) such as aluminum, copper and/or tungsten, the placement of which serves to enhance fracture resistance at the die edge.

An ion implantation mask 3014 is disposed on the front side of the semiconductor wafer 3002 over the metal 3006/dielectric 3008. As shown in FIG. 3, ion implantation mask 3014 is patterned to have an opening 3016 over the dicing street 3010 (and hence over the metal 3006 present in the dicing street 3010). Ion implantation into the metal 3006 present in the dicing street 3010 will occur through the opening 3016 in the ion implantation mask 3014, thus limiting the present embrittlement treatment to the dicing street 3010 and hence to the edge of the to-be-singulated dies (see below). Suitable materials for ion implantation mask 3014 include, but are not limited to, polymers such as photoresist masks and/or polyimides.

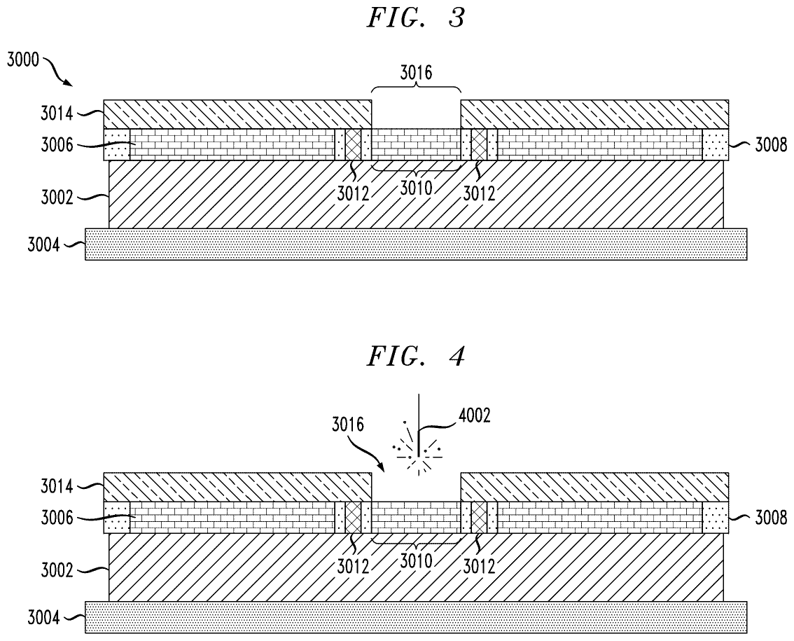

As shown in FIG. 4, ion implantation 4002 into the metal 3006 in the dicing street 3010 is performed from the front side of the semiconductor wafer 3002 through the opening 3016 in the ion implantation mask 3014. As known by those having ordinary skill in the art, ion implantation involves contacting a target material with ions of an element(s) in order to change the properties of that target material. In this case, the target material is the metal 3006 in the dicing street 3010, and the goal of the ion implantation is to change its mechanical properties in order to decrease its fracture resistance in what is referred to herein as ‘embrittlement.’

According to an exemplary embodiment, bismuth and/or hydrogen ions are implanted into the dicing street 3010 at this step. For example, in one embodiment, hydrogen ions are implanted into the dicing street 3010 by performing a heat treatment of the structure 3000 in a furnace atmosphere containing at least 10% hydrogen, preferably from about 20% to about 30% hydrogen, for a duration of from about 20 minutes to about 40 minutes at a temperature of from about 850 degrees Celsius (°C.) to about 1000° C. to produce the desired embrittlement. Alternatively, the dicing street 3010 can be selectively heated using laser technology. In another embodiment, bismuth ions are implanted into the dicing street 3010 through ion milling with an ion energy of from about 50 electron volts (eV) to about 100 eV. As will be described in detail below, embodiments are also contemplated herein where an ion beam is rastered across the surface of the structure 3000 along the dicing street, either with or without the ion implantation mask 3014. The latter, a mask-less ion implantation, advantageously simplifies the embrittlement process.

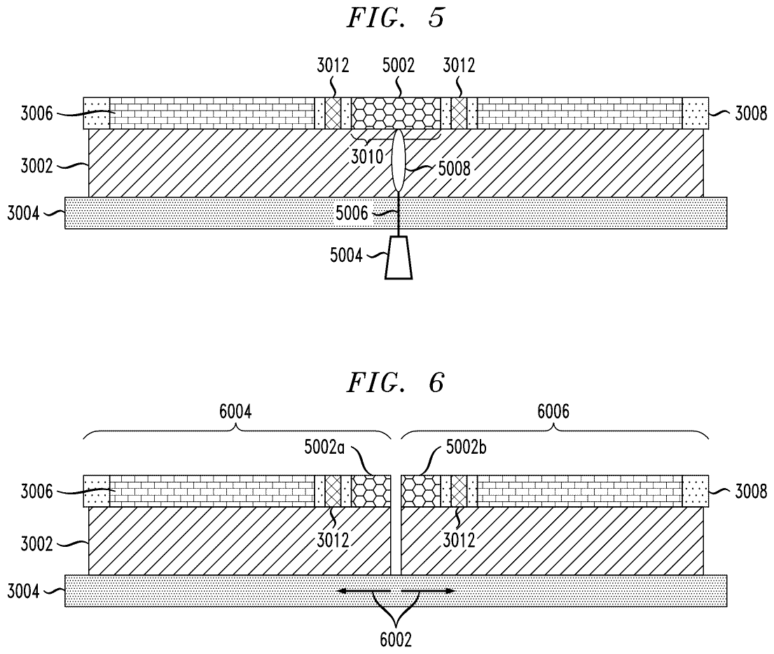

After the ion implantation, the ion implantation mask 3014 is removed. As shown in FIG. 5, as a result of the ion implantation process brittle metal 5002 (i.e., metal 3006 containing the implant) is now present in the dicing street 3010. Notably, brittle metal 5002 has a reduced fracture resistance as compared to metal 3006. For instance, as described above, when the metal 3006 present in the dicing street 3010 is copper, a bismuth implant can result in the formation of an intermetallic compound such as Cu₃Bi and/or Cu₅Bi₈ (which is the brittle metal 5002) having a different crystal structure and mechanical properties (namely reduced fracture resistance) as compared to pure copper. Namely, when subject to stress (such as expansion or stretching of the dicing tape 3004) intermetallic compounds such as Cu₃Bi and Cu₅Bi₈ will fracture more easily, and with less deformation, as compared to pure copper. Similarly, implantation of hydrogen into copper can result in the formation of a hydride such as a brittle hydride of oxygen (which is the brittle metal 5002) that has a reduced fracture resistance as compared to pure copper which, when subject to stress, will fracture more easily, and with less deformation, as compared to pure copper.

As shown in FIG. 5, stealth dicing can then be performed from the back side of the semiconductor wafer 3002. According to an exemplary embodiment, the stealth dicing is performed in two stages. In the first stage, a laser source 5004 is used to direct an ultraviolet (UV) laser 5006 from a back side of the semiconductor wafer 3002 to melt the (e.g., Si, Ge, SiGe, and/or III-V) material of the semiconductor wafer 3002 along the dicing street 3010. Doing so, results in the formation of a void 5008 in the semiconductor wafer 3002. As highlighted above, the UV laser 5006 is unable to cut metal in the dicing street 3010. However, since the metal in the dicing street 3010 is now the brittle metal 5002 (i.e., metal 3006 containing the implant), it will fracture when subject to stress during expansion of the dicing tape 3004.

Namely, in the second stage, as shown in FIG. 6, the dicing tape 3004 is expanded/stretched for separation of the semiconductor wafer 3002 into separate, individual dies 6004 and 6006 (which is referred to herein as ‘die singulation’). See arrows 6002. The brittle metal 5002 acts as a site for crack initiation and propagation during this expanding/stretching of the dicing tape 3004. Notably, following die singulation, each of dies 6004 and 6006 contains a portion 5002a and 5002b, respectively, of the brittle metal 5002 (i.e., metal 3006 containing the implant) along at least one of its edges. See FIG. 6. Specifically, portion 5002a and portion 5002b of the brittle metal 5002 are present outward of, and adjacent to, the crackstop structures 3012. Conversely, the crackstop structures 3012 are present inward of, and adjacent to, portion 5002a and portion 5002b of the brittle metal 5002. The dicing tape 3004 can then be exposed to UV light to reduce its adhesiveness, and the dies 6004 and 6006 can be picked for bonding using, e.g., a pick and place tool.

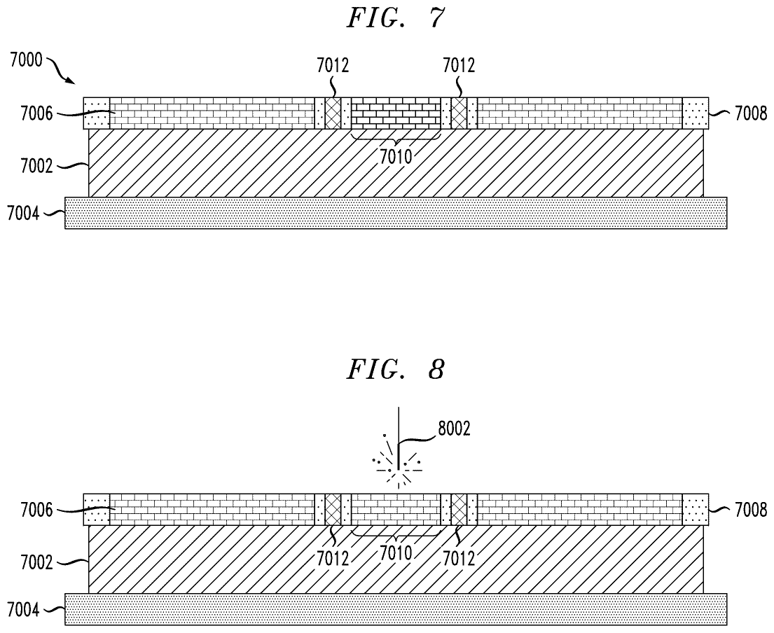

As highlighted above, embodiments are also contemplated herein where the ion implantation process is performed using rastering of an ion beam, which can optionally be implemented via a mask-less process. See, for example, FIGS. 7-10. As shown in FIG. 7, the process begins in the same general manner as the example above, with a structure 7000 that includes a semiconductor wafer 7002 (e.g., a bulk Si, bulk Ge, bulk SiGe and/or bulk III-V semiconductor wafer) mounted on a dicing tape 7004. Semiconductor wafer 7002 may have pre-built structures (not shown) such as transistors, diodes, capacitors, resistors, interconnects, wiring, etc.

Dicing tape 7004 may be any commercially-available dicing tape which includes a backing material such as PVC, polyolefin and/or polyethene, and an adhesive for attaching the dicing tape to a back side of the semiconductor wafer 7002. As above, the dicing tape 7004 will be employed later on in the process during die singulation when it is expanded to propagate fractures along the dicing street.

A metal 7006 (e.g., copper) embedded in a dielectric 7008 is disposed on a front side of the semiconductor wafer 7002, including within a dicing street 7010. While not explicitly shown, metal 7006 may be composed of multiple metal levels built one on top of another. Suitable dielectric 7008 materials include, but are not limited to, oxide low-κ materials such as SiOx and/or ULK-ILD materials, such as pSiCOH.

Crackstop structures 7012 are present on opposite sides of the dicing street 7010. By way of example only, crackstop structures 7012 can be formed from a metal(s) such as aluminum, copper and/or tungsten, the placement of which serves to enhance fracture resistance at the die edge.

As compared to the previous example, here a mask-less process is employed thereby avoiding the steps associated with forming and then subsequently removing any type of implantation mask. Accordingly, as shown in FIG. 8, the next task is to perform an ion implantation into the metal 7006 in the dicing street 7010 from the front side of the semiconductor wafer 7002 via (e.g., a bismuth and/or hydrogen ion-containing) ion beam 8002 that is rastered across the surface of the structure 7000 along the dicing street 7010. In the same manner as above, the goal of the ion implantation is to change the mechanical properties of the metal 7006 in the dicing street 7010 in order to decrease its fracture resistance in what is referred to herein as ‘embrittlement.’

According to an exemplary embodiment, bismuth and/or hydrogen ions are implanted into the dicing street 7010 at this step. For example, a commercially-available focused ion beam tool can be employed to generate the ion beam 8002 containing bismuth and/or hydrogen ions. The resulting ion beam 8002 is then rastered across the surface of the structure 7000 along the dicing street 7010.

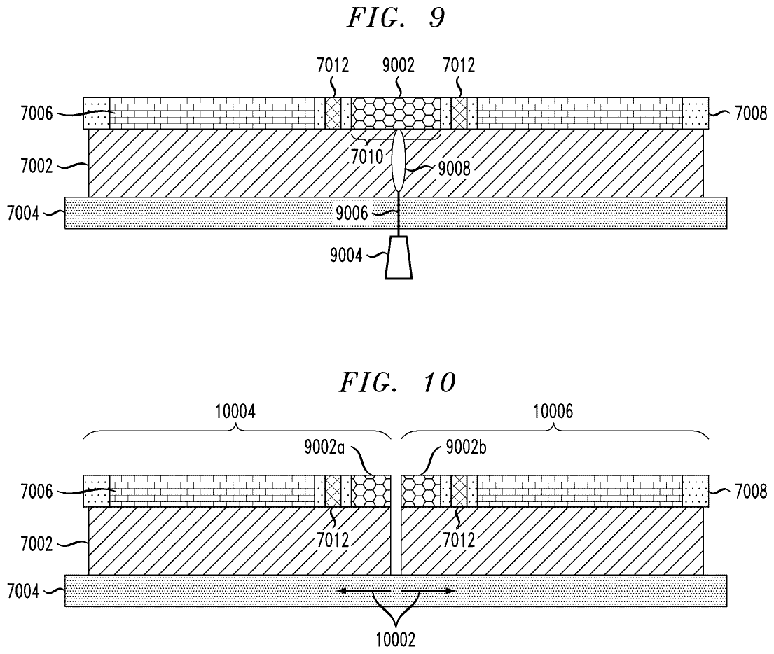

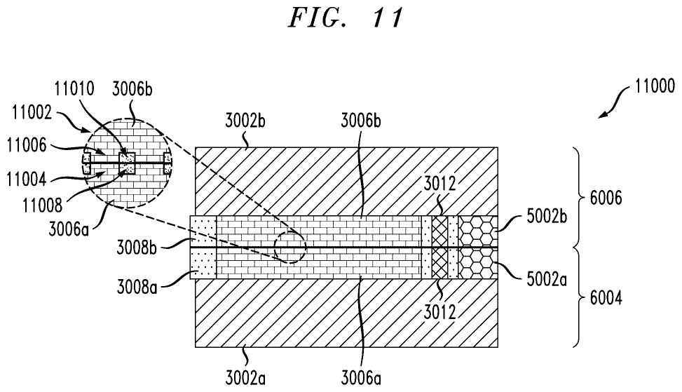

As shown in FIG. 9, as a result of the ion implantation process brittle metal 9002 (i.e., metal 7006 containing the implant) is now present in the dicing street 7010. Notably, brittle metal 9002 has a reduced fracture resistance as compared to metal 7006. For instance, as described above, when the metal 7006 present in the dicing street 7010 is copper, a bismuth implant can result in the formation of an intermetallic compound such as Cu₃Bi and/or Cu₅Bi₈ (which is the brittle metal 9002) having a different crystal structure and mechanical properties (namely reduced fracture resistance) as compared to pure copper. Namely, when subject to stress (such as expansion or stretching of the dicing tape 7004) intermetallic compounds such as Cu₃Bi and Cu₅Bi₈ will fracture more easily, and with less deformation, as compared to pure copper. Similarly, implantation of hydrogen into copper can result in the formation of a hydride such as a brittle hydride of oxygen (which is the brittle metal 9002) that has a reduced fracture resistance as compared to pure copper which, when subject to stress, will fracture more easily, and with less deformation, as compared to pure copper.

As shown in FIG. 9, stealth dicing can then be performed from the back side of the semiconductor wafer 7002. According to an exemplary embodiment, the stealth dicing is performed in two stages. In the first stage, a laser source 9004 is used to direct a UV laser 9006 from a back side of the semiconductor wafer 7002 to melt the (e.g., Si, Ge, SiGe, and/or III-V) material of the semiconductor wafer 7002 along the dicing street 7010. Doing so, results in the formation of a void 9008 in the semiconductor wafer 7002. As highlighted above, the UV laser 9006 is unable to cut metal in the dicing street 7010. However, since the metal in the dicing street 7010 is now the brittle metal 9002 (i.e., metal 7006 containing the implant), it will fracture when subject to stress during expansion of the dicing tape 7004.

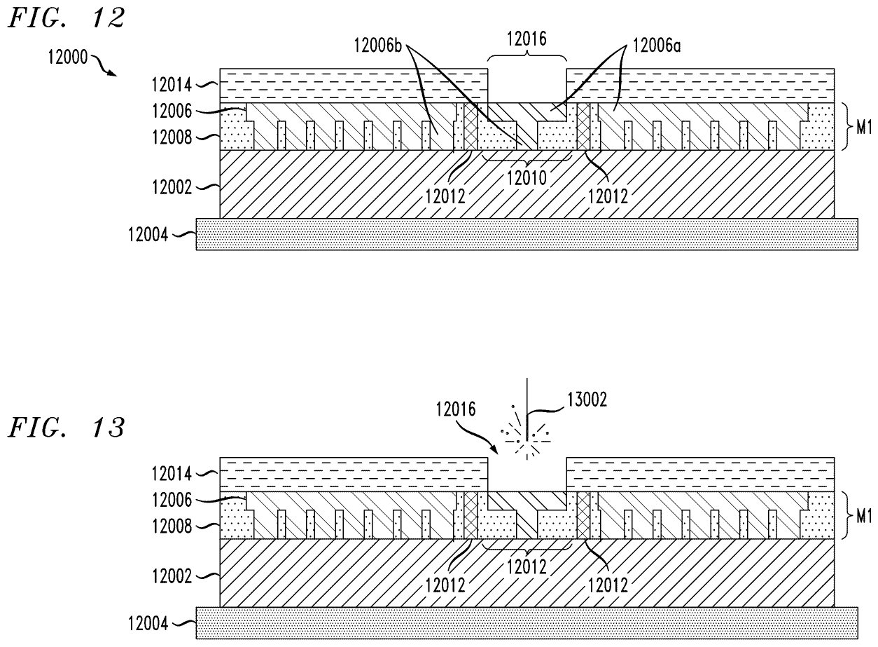

Namely, in the second stage, as shown in FIG. 10, the dicing tape 7004 is expanded/stretched for separation of the semiconductor wafer 7002 into separate, individual dies 10004 and 10006 (which is referred to herein as ‘die singulation’). See arrows 10002. The brittle metal 9002 acts as a site for crack initiation and propagation during this expanding/stretching of the dicing tape 7004. Notably, following die singulation, each of dies 10004 and 10006 contains a portion 9002a and 9002b, respectively, of the brittle metal 9002 (i.e., metal 7006 containing the implant) along at least one of its edges. See FIG. 10. Specifically, portion 9002a and portion 9002b of the brittle metal 9002 are present outward of, and adjacent to, the crackstop structures 7012. Conversely, the crackstop structures 7012 are present inward of, and adjacent to, portion 9002a and portion 9002b of the brittle metal 9002. The dicing tape 7004 can then be exposed to UV light to reduce its adhesiveness, and the dies 10004 and 10006 can be picked for bonding using, e.g., a pick and place tool.

As described in detail above, the singulated dies resulting from the present Embrittlement Enhanced Stealth Dicing (EESD) process are ideal for hybrid bonding applications due, for example, to the lack of debris and/or remelt on the semiconductor wafer surface. For instance, an example involving the face-to-face hybrid bonding of two of the present EESD-produced dies 6004 (also referred to herein generally as a “first component”) and 6006 (also referred to herein generally as a “second component”) is shown illustrated in FIG. 11. It is notable that the dies 6004 and 6006 of FIG. 6 are being used merely as an illustrative, non-limiting example, and that any of the die configurations provided herein are suitable for hybrid bonding.

Accordingly, dies 6004 and 6006 contain the same components as described in conjunction with the description of FIG. 6, above, and that like structures are numbered alike in the figures. However, for clarity of description, portions 3002a and 3002b of the semiconductor wafer 3002 associated with dies 6004 and 6006 respectively are now individually designated, portions 3006a and 3006b of the metal 3006 associated with dies 6004 and 6006 respectively are now individually designated, and portions 3008a and 3008b of the dielectric 3008 associated with dies 6004 and 6006 respectively are now individually designated.

To enable face-to-face bonding, die 6006 is flipped (as compared to the orientation of die 6006 shown in FIG. 6) so that the die 6004 and the die 6006 are facing one another. Hybrid bonding is then used to join dies 6004 and 6006 together, forming a semiconductor device 11000. As highlighted above, hybrid bonding is a thermo-compressive bonding process that combines both dielectric and metal bonding to form interconnections. More specifically, referring to magnified view 11002, it can be seen that the portion 3006a of the metal 3006 on die 6004 actually contains metal pads 11004 embedded in a dielectric 11008. Similarly, the portion 3006b of the metal 3006 on die 6006 contains corresponding metal pads 11006 embedded in a dielectric 11010. This enables die 6004 to be bonded to die 6006 via a combination of metal bonds between the metal pads 11004 and the metal pads 1106 respectively, and dielectric bonds between the dielectric 11008 and the dielectric 11010 respectively, i.e., hybrid bonding.

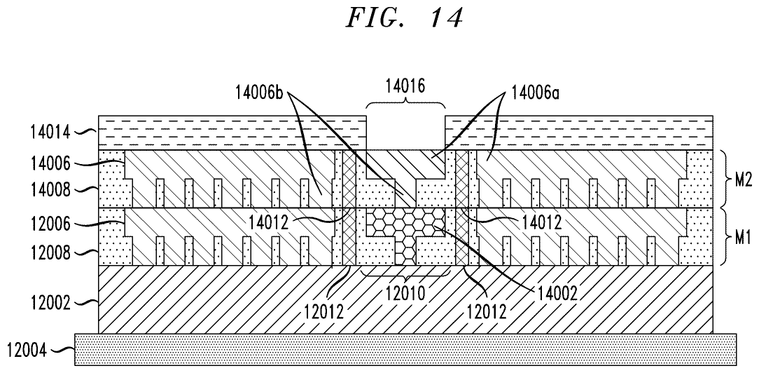

Embodiments are also contemplated herein where the present ion implantation for embrittlement of metal in the dicing street is carried out as each one of multiple metal levels is formed on a semiconductor wafer, followed by die singulation using the instant (embrittlement enhanced) stealth dicing. See, for example, FIGS. 12-17. For example, referring to FIG. 12, the process begins with a structure 12000 similar to those above that includes a semiconductor wafer 12002 (e.g., a bulk Si, bulk Ge, bulk SiGe and/or bulk III-V semiconductor wafer) mounted on a dicing tape 12004. Semiconductor wafer 12002 may have pre-built structures (not shown) such as transistors, diodes, capacitors, resistors, interconnects, wiring, etc.

Dicing tape 12004 may be any commercially-available dicing tape which includes a backing material such as PVC, polyolefin and/or polyethene, and an adhesive for attaching the dicing tape to a back side of the semiconductor wafer 12002. As highlighted above, the dicing tape 12004 will be employed later on in the process during die singulation when it is expanded to propagate fractures along the dicing street.

A metal 12006 (e.g., copper) embedded in a dielectric 12008 is disposed on a front side of the semiconductor wafer 12002, including within a dicing street 12010. In this particular example, the metal 12006 includes interconnect structures 12006a and 12006b that make horizontal/lateral and vertical connections, respectively. Standard metallization processes such as so-called damascene and/or dual damascene processes can be employed to form these (horizontal and vertical) interconnect structures 12006a and 12006b. Further, as will become apparent from the description that follows, multiple metal levels will be built on the semiconductor wafer 12002 in this example. Thus, for ease and clarity of description, metal 12006 and dielectric 12008 may be collectively referred to herein as a first metal level or metal level M1. As above, suitable dielectric 12008 materials include, but are not limited to, oxide low-κ materials such as SiOx and/or ULK-ILD materials, such as pSiCOH.

As shown in FIG. 12, crackstop structures 12012 are present on opposite sides of the dicing street 12010. By way of example only, crackstop structures 12012 can be formed from a metal(s) such as aluminum, copper and/or tungsten, the placement of which serves to enhance fracture resistance at the die edge.

An ion implantation mask 12014 is disposed on the front side of the semiconductor wafer 12002 over the metal level M1 (i.e., metal 12006/dielectric 12008). As shown in FIG. 12, ion implantation mask 12014 is patterned to have an opening 12016 over the dicing street 12010 (and hence over the metal 12006 present in the dicing street 12010). Ion implantation into the metal 12006 present in the dicing street 12010 will occur through the opening 12016 in the ion implantation mask 12014, thus limiting the present embrittlement treatment to the dicing street 12010 and hence to the edge of the to-be-singulated dies (see below). As above, suitable materials for ion implantation mask 12014 include, but are not limited to, polymers such as photoresist masks and/or polyimides.

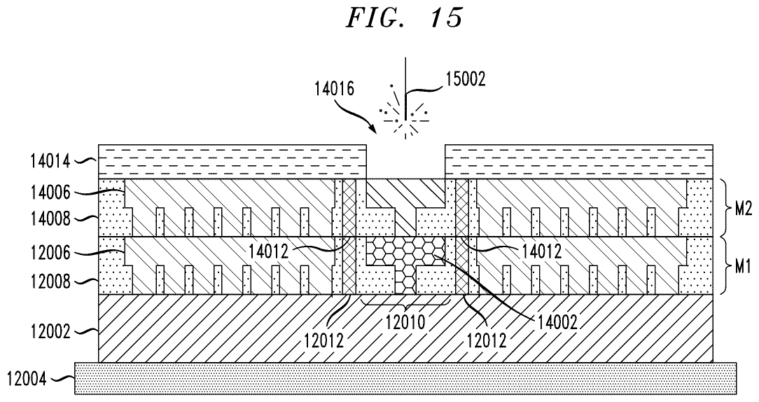

As shown in FIG. 13, ion implantation into the metal 12006 in the dicing street 12010 is performed from the front side of the semiconductor wafer 12002 through the opening 12016 in the ion implantation mask 12014. In the same manner as above, the goal of the ion implantation is to change the mechanical properties of the metal 12006 (of the metal level M1) in the dicing street 12010 in order to decrease its fracture resistance in what is referred to herein as ‘embrittlement.’

According to an exemplary embodiment, bismuth and/or hydrogen ions are implanted into the dicing street 12010 at this step. For instance, in the same manner as described above, a bismuth and/or hydrogen ion-containing ion beam 13002 can be used to introduce bismuth and/or hydrogen implants into the dicing street 12010 through the opening 12016 in the ion implantation mask 12014. Further, as described in detail above, embodiments are also contemplated herein where an ion beam is rastered across the surface of the structure 12000 along the dicing street, either with or without the ion implantation mask 12014, the latter being a mask-less ion implantation.

After the ion implantation, the ion implantation mask 12014 is removed. As shown in FIG. 14, as a result of the ion implantation process brittle metal 14002 (i.e., metal 12006 containing the implant) is now present in the dicing street 12010. Notably, brittle metal 14002 has a reduced fracture resistance as compared to metal 12006. For instance, as described above, when the metal 12006 present in the dicing street 12010 is copper, a bismuth implant can result in the formation of an intermetallic compound such as Cu₃Bi and/or Cu₅Bi₈ (which is the brittle metal 14002) having a different crystal structure and mechanical properties (namely reduced fracture resistance) as compared to pure copper. Namely, when subject to stress (such as expansion or stretching of the dicing tape 12004) intermetallic compounds such as Cu₃Bi and Cu₅Bi₈ will fracture more easily, and with less deformation, as compared to pure copper. Similarly, implantation of hydrogen into copper can result in the formation of a hydride such as a brittle hydride of oxygen (which is the brittle metal 14002) that has a reduced fracture resistance as compared to pure copper which, when subject to stress, will fracture more easily, and with less deformation, as compared to pure copper.

As shown in FIG. 14, the above-described process is then repeated to build one or more additional metal levels on top of metal level M1, followed by masking and ion implantation after each metal level is formed. For instance, as shown in FIG. 14, a second metal level or metal level M2 is next formed on the front side of the semiconductor wafer 12002 over the metal level M1. This metal level M2 includes a metal 14006 (e.g., copper) embedded in a dielectric 14008, including within the dicing street 12010. Like metal 12006 above, the metal 14006 also includes interconnect structures 14006a and 14006b that make horizontal/lateral and vertical connections, respectively. Standard metallization processes such as so-called damascene and/or dual damascene processes can be employed to form these (horizontal and vertical) interconnect structures 14006a and 14006b. As above, suitable dielectric 14008 materials include, but are not limited to, oxide low-κ materials such as SiOx and/or ULK-ILD materials, such as pSiCOH. Similarly, crackstop structures 14012 are implemented on opposite sides of the dicing street 12010 to enhance fracture resistance at the die edge.

An ion implantation mask 14014 is formed on the metal level M2 (i.e., metal 14006/dielectric 14008). For clarity, the terms “first” and “second” may also be used herein when referring to ion implantation mask 12014 and ion implantation mask 14014, respectively. As shown in FIG. 14, ion implantation mask 14014 is also patterned to have an opening 14016 over the dicing street 12010 (and hence over the metal 14006 present in the dicing street 12010). As above, suitable materials for ion implantation mask 14014 include, but are not limited to, polymers such as photoresist masks and/or polyimides.

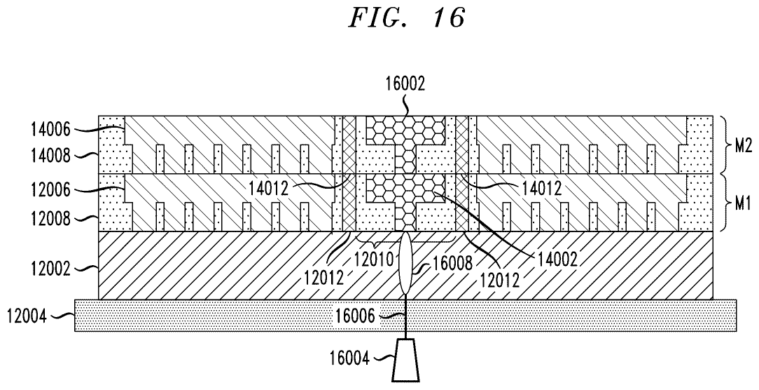

As shown in FIG. 15, ion implantation into the metal 14006 in the dicing street 12010 is performed from the front side of the semiconductor wafer 12002 through the opening 14016 in the ion implantation mask 14014. In the same manner as above, the goal of the ion implantation is to change the mechanical properties of the metal 14006 (of the metal level M2) in the dicing street 12010 in order to decrease its fracture resistance (i.e., embrittlement).

According to an exemplary embodiment, bismuth and/or hydrogen ions are implanted into the dicing street 12010 at this step. For instance, in the same manner as described above, a bismuth and/or hydrogen ion-containing ion beam 15002 can be used to introduce bismuth and/or hydrogen implants into the dicing street 12010 through the opening 14016 in the ion implantation mask 14014. Following ion implantation into the metal level M2, the ion implantation mask 14014 is removed.

Optionally, multiple iterations of the steps depicted in FIGS. 12-15, and described above, can be performed to build additional metal levels, e.g., M1, M2, . . . , Mx, as desired. As known by those having ordinary skill in the art, these metal levels are generally part of what is commonly referred to as the Back-End-of-Line or BEOL, and any additional metal levels may be added until the BEOL is complete.

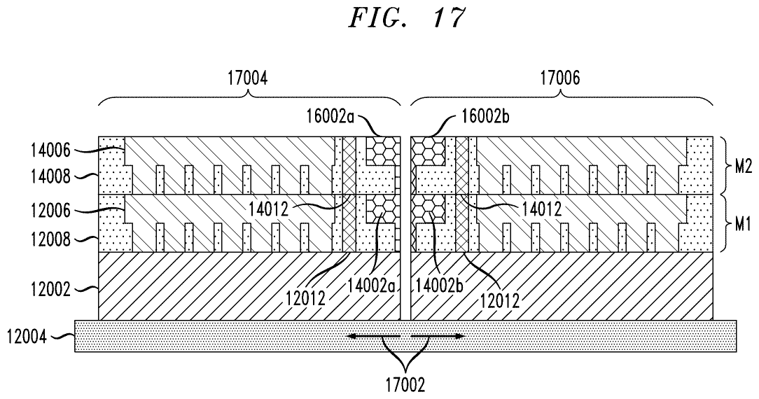

Once the BEOL is complete, stealth dicing can then be performed from the back side of the semiconductor wafer 12002. Namely, as shown in FIG. 16, as a result of the ion implantation process on metal level M2 brittle metal 16002 (i.e., metal 14006 containing the implant) is now present in the dicing street 12010 which has a reduced fracture resistance as compared to metal 14006.

According to an exemplary embodiment, the stealth dicing is performed in two stages. In the first stage, a laser source 16004 is used to direct a UV laser 16006 from a back side of the semiconductor wafer 12002 to melt the (e.g., Si, Ge, SiGe, and/or III-V) material of the semiconductor wafer 12002 along the dicing street 12010. Doing so, results in the formation of a void 16008 in the semiconductor wafer 12002. As highlighted above, the UV laser 16006 is unable to cut metal in the dicing street 12010. However, since the metal in the dicing street 12010 is now the brittle metal 14002 (i.e., metal 12006 containing the implant), brittle metal 16002 (i.e., metal 14006 containing the implant), etc. it will fracture when subject to stress during expansion of the dicing tape 12004.

Namely, in the second stage, as shown in FIG. 17, the dicing tape 12004 is expanded/stretched for separation of the semiconductor wafer 12002 into separate, individual dies 17004 and 17006 (which is referred to herein as ‘die singulation’). See arrows 17002. The brittle metal 14002, brittle metal 16002, etc. act as a site for crack initiation and propagation during this expanding/stretching of the dicing tape 12004. Notably, following die singulation, each of dies 17004 and 17006 contains a portion 14002a, 16002a, etc. and 14002b, 16002b, etc., respectively, of the brittle metal 14002 (i.e., metal 12006 containing the implant), brittle metal 16002 (i.e., metal 14006 containing the implant), etc. along at least one of its edges. See FIG. 17. The dicing tape 12004 can then be exposed to UV light to reduce its adhesiveness, and the dies 17004 and 17006 can be picked for bonding using, e.g., a pick and place tool.

Accordingly, in this present example, the metal, i.e., metal 12006, metal 14006, etc., is present in multiple metal levels, i.e., metal level M1, metal level M2, etc. The (optional) ion implantation masking and implant for embrittling the metal, i.e., metal 12006, metal 14006, etc., are performed after the fabrication of each metal level and prior to performing the stealth dicing.

Semiconductor device manufacturing includes various steps of device patterning processes. For example, the manufacturing of a semiconductor chip may start with, for example, a plurality of CAD (computer aided design) generated device patterns, which is then followed by effort to replicate these device patterns in a substrate. The replication process may involve the use of various exposing techniques and a variety of subtractive (etching) and/or additive (deposition) material processing procedures. For example, in a photolithographic process, a layer of photo-resist material may first be applied on top of a substrate, and then be exposed selectively according to a pre-determined device pattern or patterns. Portions of the photo-resist that are exposed to light or other ionizing radiation (e.g., ultraviolet, electron beams, X-rays, etc.) may experience some changes in their solubility to certain solutions. The photo-resist may then be developed in a developer solution, thereby removing the non-irradiated (in a negative resist) or irradiated (in a positive resist) portions of the resist layer, to create a photo-resist pattern or photo-mask. The photo-resist pattern or photo-mask may subsequently be copied or transferred to the substrate underneath the photo-resist pattern.

There are numerous techniques used by those skilled in the art to remove material at various stages of creating a semiconductor structure. As used herein, these processes are referred to generically as “etching”. For example, etching includes techniques of wet etching, dry etching, chemical oxide removal (COR) etching, and reactive ion etching (RIE), which are all known techniques to remove select material(s) when forming a semiconductor structure. The Standard Clean 1 (SC1) contains a strong base, typically ammonium hydroxide, and hydrogen peroxide. The SC2 contains a strong acid such as hydrochloric acid and hydrogen peroxide. The techniques and application of etching is well understood by those skilled in the art and, as such, a more detailed description of such processes is not presented herein.

Although the overall fabrication method and the structures formed thereby are novel, certain individual processing steps required to implement the method may utilize conventional semiconductor fabrication techniques and conventional semiconductor fabrication tooling. These techniques and tooling will already be familiar to one having ordinary skill in the relevant arts given the teachings herein. Moreover, one or more of the processing steps and tooling used to fabricate semiconductor devices are also described in a number of readily available publications, including, for example: James D. Plummer et al., Silicon VLSI Technology: Fundamentals, Practice, and Modeling 1^{st} Edition, Prentice Hall, 2001 and P. H. Holloway et al., Handbook of Compound Semiconductors: Growth, Processing, Characterization, and Devices, Cambridge University Press, 2008, which are both hereby incorporated by reference herein. It is emphasized that while some individual processing steps are set forth herein, those steps are merely illustrative, and one skilled in the art may be familiar with several equally suitable alternatives that would be applicable.

It is to be appreciated that the various layers and/or regions shown in the accompanying figures may not be drawn to scale. Furthermore, one or more semiconductor layers of a type commonly used in such integrated circuit devices may not be explicitly shown in a given figure for ease of explanation. This does not imply that the semiconductor layer(s) not explicitly shown are omitted in the actual integrated circuit device.

Given the discussion thus far, it will be appreciated that, in general terms, an exemplary semiconductor device 11000 includes: at least one die (e.g., dies 6004/6006, dies 10004/10006, etc.) having a metal (e.g., metal 3006, metal 7006, etc.) disposed on a semiconductor wafer (e.g., semiconductor wafer 3002, semiconductor wafer 7002, etc.), where a portion of the metal present along at least one edge of the at least one die (e.g., portion 5002a/5002b of brittle metal 5002, portion 9002a/9002b of brittle metal 9002, etc.) includes an implant selected from: bismuth, hydrogen, and combinations thereof.

In accordance with another aspect of the invention, an exemplary semiconductor device 11000 includes: a first component (e.g., die 6004, die 10004, etc.) bonded to a second component (e.g., die 6006, die 10006, etc.) via a combination of metal and dielectric bonds, where the first component, the second component or both the first component and the second component includes a die (e.g., die 6004 and/or die 6006, die 10004 and/or die 10006, etc.) having a metal (e.g., metal 3006, metal 7006, etc.) disposed on a semiconductor wafer (e.g., semiconductor wafer 3002, semiconductor wafer 7002, etc.), and where a portion of the metal present along at least one edge of the die (e.g., portion 5002a/5002b of brittle metal 5002, portion 9002a/9002b of brittle metal 9002, etc.) comprises an implant selected from the group consisting of: bismuth, hydrogen, and combinations thereof.

In accordance with yet another aspect of the invention, an exemplary method includes: embrittling a metal (e.g., metal 3006, metal 7006, etc.) disposed on a front side of a semiconductor wafer (e.g., semiconductor wafer 3002, semiconductor wafer 7002, etc.) that is mounted on a dicing tape (e.g., dicing tape 3004, dicing tape 7004, etc.) to form a brittle metal (e.g., brittle metal 5002, brittle metal 9002, etc.) in a dicing street (e.g., dicing street 3010, dicing street 7010, etc.) of the semiconductor wafer; using a laser (e.g., UV laser 5006, UV laser 9006, etc.) from a back side of the semiconductor wafer to melt the semiconductor wafer along the dicing street of the semiconductor wafer; and expanding the dicing tape to separate the semiconductor wafer into individual dies (e.g., dies 6004/6006, dies 10004/10006, etc.), where the brittle metal in the dicing street of the semiconductor wafer acts as site for crack initiation and propagation during the expanding of the dicing tape.

Those skilled in the art will appreciate that the exemplary structures discussed above can be distributed in raw form (i.e., a single wafer having multiple unpackaged chips), as bare dies, in packaged form, or incorporated as parts of intermediate products or end products that benefit from use of one or more aspects of the disclosed Embrittlement Enhanced Stealth Dicing (EESD) techniques.

An integrated circuit in accordance with aspects of the present inventions can be employed in essentially any application and/or electronic system where one or more aspects of the disclosed EESD techniques would be beneficial. Given the teachings of the present disclosure provided herein, one of ordinary skill in the art will be able to contemplate other implementations and applications of embodiments disclosed herein.

The illustrations of embodiments described herein are intended to provide a general understanding of the various embodiments, and they are not intended to serve as a complete description of all the elements and features of apparatus and systems that might make use of the circuits and techniques described herein. Many other embodiments will become apparent to those skilled in the art given the teachings herein; other embodiments are utilized and derived therefrom, such that structural and logical substitutions and changes can be made without departing from the scope of this disclosure. It should also be noted that, in some alternative implementations, some of the steps of the exemplary methods may occur out of the order noted in the figures. For example, two steps shown in succession may, in fact, be executed substantially concurrently, or certain steps may sometimes be executed in the reverse order, depending upon the functionality involved. The drawings are also merely representational and are not drawn to scale. Accordingly, the specification and drawings are to be regarded in an illustrative rather than a restrictive sense.

Embodiments are referred to herein, individually and/or collectively, by the term “embodiment” merely for convenience and without intending to limit the scope of this application to any single embodiment or inventive concept if more than one is, in fact, shown. Thus, although specific embodiments have been illustrated and described herein, it should be understood that an arrangement achieving the same purpose can be substituted for the specific embodiment(s) shown; that is, this disclosure is intended to cover any and all adaptations or variations of various embodiments. Combinations of the above embodiments, and other embodiments not specifically described herein, will become apparent to those of skill in the art given the teachings herein.

The terminology used herein is for the purpose of describing particular embodiments only and is not intended to be limiting. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, steps, operations, elements, and/or components, but do not preclude the presence or addition of one or more other features, steps, operations, elements, components, and/or groups thereof. Terms such as “bottom”, “top”, “above”, “over”, “under” and “below” are used to indicate relative positioning of elements or structures to each other as opposed to relative elevation. If a layer of a structure is described herein as “over” another layer, it will be understood that there may or may not be intermediate elements or layers between the two specified layers. If a layer is described as “directly on” another layer, direct contact of the two layers is indicated. As the term is used herein and in the appended claims, “about” means within plus or minus ten percent.

The corresponding structures, materials, acts, and equivalents of any means or step-plus-function elements in the claims below are intended to include any structure, material, or act for performing the function in combination with other claimed elements as specifically claimed. The description of the various embodiments has been presented for purposes of illustration and description, but is not intended to be exhaustive or limited to the forms disclosed. Many modifications and variations will be apparent to those of ordinary skill in the art without departing from the scope and spirit thereof. The embodiments were chosen and described in order to best explain principles and practical applications, and to enable others of ordinary skill in the art to understand the various embodiments with various modifications as are suited to the particular use contemplated.

The abstract is provided to comply with 37 C.F.R. § 1.76(b), which requires an abstract that will allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in a single embodiment for the purpose of streamlining the disclosure. This method of disclosure is not to be interpreted as reflecting an intention that the claimed embodiments require more features than are expressly recited in each claim. Rather, as the appended claims reflect, the claimed subject matter may lie in less than all features of a single embodiment. Thus, the following claims are hereby incorporated into the Detailed Description, with each claim standing on its own as separately claimed subject matter.

Given the teachings provided herein, one of ordinary skill in the art will be able to contemplate other implementations and applications of the techniques and disclosed embodiments. Although illustrative embodiments have been described herein with reference to the accompanying drawings, it is to be understood that illustrative embodiments are not limited to those precise embodiments, and that various other changes and modifications are made therein by one skilled in the art without departing from the scope of the appended claims.

What is claimed is:

1. A semiconductor device, comprising:
at least one die having a metal disposed on a semiconductor wafer, wherein a portion of the metal present along at least one edge of the at least one die comprises an implant selected from the group consisting of: bismuth, hydrogen, and combinations thereof.

2. The semiconductor device of claim 1, wherein the metal comprises copper.

3. The semiconductor device of claim 2, wherein the implant comprises bismuth, and wherein the portion of the metal present along the at least one edge of the at least one die comprises an intermetallic compound selected from the group consisting of: Cu₃Bi, Cu₅Bi₈, and combinations thereof.

4. The semiconductor device of claim 2, wherein the implant comprises hydrogen, and wherein the portion of the metal present along the at least one edge of the at least one die comprises a hydride.

5. The semiconductor device of claim 1, wherein only the portion of the metal present along the at least one edge of the at least one die comprises the implant.

6. The semiconductor device of claim 4, wherein the at least one edge of the at least one die comprises a region along a perimeter of the at least one die that is from about 300 nanometers (nm) to about 500 nm in from an outermost side of the at least one die.

7. The semiconductor device of claim 1, further comprising:
a crack stop structure adjacent to the portion of the metal present along the at least one edge of the at least one die that comprises the implant.

8. A semiconductor device, comprising:
a first component bonded to a second component via a combination of metal and dielectric bonds, wherein the first component, the second component or both the first component and the second component comprises a die having a metal disposed on a semiconductor wafer, and wherein a portion of the metal present along at least one edge of the die comprises an implant selected from the group consisting of: bismuth, hydrogen, and combinations thereof.

9. The semiconductor device of claim 8, wherein the metal comprises copper, wherein the implant comprises bismuth, and wherein the portion of the metal present along the at least one edge of the die comprises an intermetallic compound selected from the group consisting of: Cu₃Bi, Cu₅Bi₈, and combinations thereof.

10. The semiconductor device of claim 8, wherein the metal comprises copper, wherein the implant comprises hydrogen, and wherein the portion of the metal present along the at least one edge of the die comprises a hydride.

11. The semiconductor device of claim 8, wherein only the portion of the metal present along the at least one edge of the die comprises the implant.

12. The semiconductor device of claim 11, wherein the at least one edge of the die comprises a region along a perimeter of the die that is from about 300 nanometers (nm) to about 500 nm in from an outermost side of the die.

13. The semiconductor device of claim 8, further comprising:
a crack stop structure adjacent to the portion of the metal present along the at least one edge of the die that comprises the implant.

14. A method, comprising:
embrittling a metal disposed on a front side of a semiconductor wafer that is mounted on a dicing tape to form a brittle metal in a dicing street of the semiconductor wafer;
using a laser from a back side of the semiconductor wafer to melt the semiconductor wafer along the dicing street of the semiconductor wafer; and
expanding the dicing tape to separate the semiconductor wafer into individual dies, wherein the brittle metal in the dicing street of the semiconductor wafer acts as a site for crack initiation and propagation during the expanding of the dicing tape.

15. The method of claim 14, wherein the embrittling comprises:
implanting an implant into the metal present in the dicing street of the semiconductor wafer using ion implantation to form the brittle metal, wherein the implant is selected from the group consisting of: bismuth, hydrogen, and combinations thereof.

16. The method of claim 15, wherein an ion implantation mask is disposed on the front side of the semiconductor wafer, and wherein the implanting is performed through the ion implantation mask.

17. The method of claim 15, wherein the implanting is performed using an ion beam that is rastered along the dicing street of the semiconductor wafer.

18. The method of claim 15, wherein the metal comprises copper and the implant comprises bismuth, and wherein the brittle metal comprises an intermetallic compound selected from the group consisting of: Cu₃Bi, Cu₅Bi₈, and combinations thereof.

19. The method of claim 15, wherein the metal comprises copper and the implant comprises hydrogen, and wherein the brittle metal comprises a hydride.

20. The method of claim 14, wherein the metal is present in multiple metal levels formed on the front side of the semiconductor wafer, and wherein the embrittling is performed after each of the multiple metal levels is formed on the front side of the semiconductor wafer.
